(19) United States
(12) Patent Application Publication
(10) Pub. No.: US 2003/0014861 A1
(43) Pub. Date: Jan. 23, 2003

(54) Method of making an apparatus bushing with silicone-rubber housing

(76) Inventors: Robert A. Krol, North Charleston, SC (US); Christopher J. Wetherill, Woodruff, SC (US)

Correspondence Address: Luke Anderson, Esq., McGuireWoods LLP, Bank of America Corporate Center, 100 N. Tryon Street, Suite 2900, Charlotte, NC, 28202, US

(21) Appl. No.: 10/246,923

(22) Filed: Sep. 18, 2002

Related U.S. Application Data
(62) Division of application No. 10/062,679, filed on Jan. 30, 2002.
(60) Provisional application No. 60/266,080, filed on Feb. 2, 2001.

(51) Int. Cl. H05K 3/00; H05K 3/30

(52) U.S. Cl. 29/829; 29/846; 29/841

(57) ABSTRACT

The present invention is an oil-free apparatus bushing with a silicone-rubber housing bonded directly to a capacitance graded core, and a method for making an apparatus bushing with a silicone-rubber housing. The silicone-rubber housing has numerous performance, environmental, and safety advantages over the traditional oil filed porcelain bushings that are well known in the art.

### PRIORITY

This is a divisional application of the related co-pending application, Ser. No. 10/062,679, filed on Jan. 30, 2002, which claims priority from the related provisional patent application, Serial No. 60/266,080, filed on Feb. 2, 2001.

### DESCRIPTION

### Background of the Invention

1. Field of the Invention

The present invention generally relates to apparatus bushings, and more particularly, to a silicone-rubber housing bonded directly to the core of an apparatus bushing, which eliminates the need for a dielectric filler inside the bushing.

2. Background Description

Apparatus bushings are commonly used for conducting electricity and transitioning power lines into transformers and other electrical hardware. There are many types of electrical apparatus bushing designs. For example, dry type bushings, oil impregnated paper core bushings, and resin impregnated paper core bushings. Dry type bushings generally have porcelain housings, also commonly referred to as porcelain bushings that are brittle and susceptible to breakage. Porcelain bushings are also heavy and difficult to handle. Dirt and salt can also coat the porcelain bushing housing, forming a coating capable of conducting electricity, that increases the possibility of flashover and reduces the performance characteristics of the bushing.

Oil impregnated paper core and paper-resin capacitor bushings are well known in the industry too, and require a dielectric filler and oil around the core. The oil inside the bushing is prone to leaking, which reduces the bushing's performance and contaminates the environment. Oil Leakage is most frequently attributed to cracks in the gaskets used to seal the oil in around the core. When oil seeps out, moisture can seep in to the oil reservoir and accumulate. Moisture in the oil around the core further reduces the dielectric capacity of the core and remaining oil. Such a reduction in dielectric capacity can cause electric arcing, catastrophic failure, and the resulting spray of porcelain shrapnel that can damage near by equipment and injure people.

The present invention is directed to overcoming one or more of the problems as set forth above.

### SUMMARY OF THE INVENTION

A first aspect of the present invention is the apparatus bushing is oil-free which exhibits superior performance characteristics and has added flexibility of use compared to the traditional oil-filled bushings commonly known in the art.

Another aspect of the present invention is the silicone-rubber housing on the apparatus bushing eliminates moisture ingress, which is commonly known in the art, by bonding the silicone-rubber housing directly to the core, thus eliminating the need for gaskets that can crack and unseat to allow moisture ingress into the bushing.

Still another aspect of the present invention is the apparatus bushing can be mounted in any orientation since it is oil-free and does not require an oil reservoir that needs to be filled when the bushing is installed and eliminates the accidental overfilling of the bushing with oil that results in environmental contamination. Thus, the apparatus bushing provides greater flexibility of use and application.

Still another aspect of the present invention is when a violent failure of the apparatus bushing occurs, the silicone-rubber housing will not produce any harmful flying debris of dangerous porcelain the way the traditional oil-filled bushing with a porcelain housing would.

Still another aspect of the present invention is the silicone-rubber housing's smooth, hydrophobic surface offers superior performance in contaminated environments compared to the traditional porcelain surfaces commonly known in the art because the hydrophobic properties of the silicone-rubber housing permit isolation and insulation of surface contamination such as sea salt, industrial pollution, agricultural dust, chemical deposits, and the like.

In a preferred embodiment of the invention the apparatus bushing has an oil-free, paper-foil capacitor core containing conductive layers of aluminum foil and high dielectric paper wound together around the stud to form the bushing core, and produce uniformly valued capacitors in series. A flange is securely fastened to the capacitor core with a potting adhesive. The silicone-rubber housing is molded directly onto the capacitance core by placing the capacitor core and flange assembly in a mold and introducing liquid silicone-rubber into the mold.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows a preferred embodiment of an apparatus bushing;

FIG. 2 shows a cross section of an apparatus bushing;

FIGS. 3 through 5 show performance charts.

### DETAILED DESCRIPTION OF A PREFERRED EMBODIMENT OF THE INVENTION

The present invention is directed to an oil-free apparatus bushing with a silicone-rubber housing, more specifically with a silicone-rubber housing bonded directly to the apparatus bushing's core.

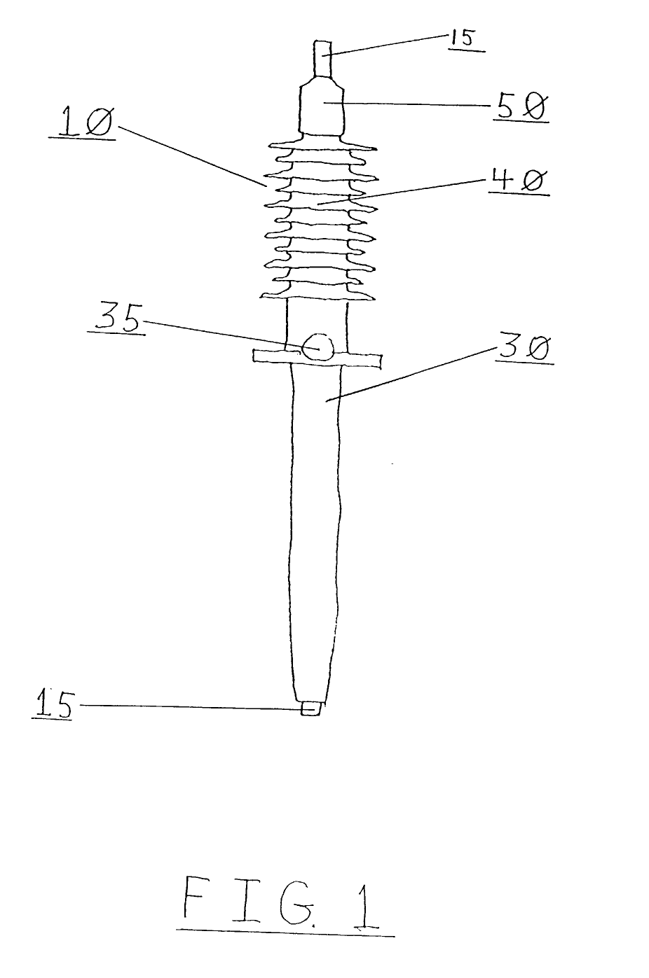

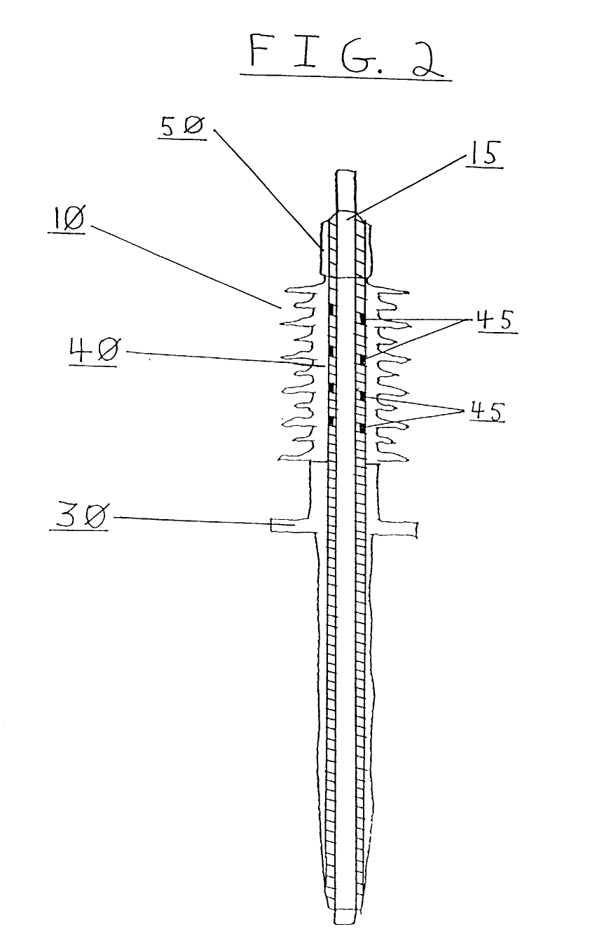

Referring now to FIG. 1, the preferred embodiment of the apparatus bushing 10 has a center core 15 of either an aluminum or copper stud that extends the entire lateral distance of the apparatus bushing 10. Multiple layers of a crepe paper, foil matrix 20 are wound around a core 15 to form a capacitance-graded core. A flange 30, that is adapted to receive the core 15, is securely fastened to the lower half of the apparatus bushing 10 with an adhesive commonly known in the art as potting adhesive. The flange 30, typically made of aluminum, provides mechanical strength and protection to the core 15, while also providing a mounting surface for securing the apparatus bushing 10 to an electric transformer or other device. A power factor test tap 35 may also be included on the flange 30 for testing the power factor of the apparatus bushing 10. The power factor test tap 35 is connected to an electrical lead wire that is also connected to the foil matrix 20 around the core 15.

The silicone-rubber housing 40 is bonded directly to the core 15, and continuously from the top of the silicone-rubber housing 40 to the bottom. In preparation for the bonding of the silicone-rubber housing 40, the core 15 is turned on a lathe to provide a smooth finished surface and cut a series of recesses 45 about an inch wide and a half-inch deep into the core 15. These recesses 45 form a channel which, when filed with silicone-rubber, provide a physical—mechanical lock that helps secure the silicone-rubber housing 40 to the core 15. The preferred embodiment has a silicone-rubber housing 40 cast from a free-flowing, addition-curing, liquid silicone-rubber. When the silicone-rubber vulcanizes it forms a rigid, yet pliable silicone-rubber housing 40 with superior electrical properties that exceed industry standards. One source of liquid silicone-rubber is Wacker Chemie, GmbH's Powersil®600.

Depending on the apparatus bushing's 10 desired application, a draw lead terminal 50 may be attached to the top of the apparatus bushing 10 by a positioning pin and retaining nut. Alternatively, a threaded screw-on cap may be attached to the top of the apparatus bushing 10.

### DETAILED METHOD OF MANUFACTURING THE PREFERRED EMBODIMENT OF THE INVENTION

The method for making the preferred embodiment begins by securely attaching a plurality of crepe paper, foil matrix layers 20 to a core 15 by winding each layer around the core 15. The foil matrix layers 20 are made of conductive media selected from the group consisting of: a metal, a conductive ink, a conductive element of paper, or other conductive media commonly known in the art. The most common conductive media metals are aluminum and copper. Conductive inks are generally comprised of a blend of powdered silver and carbon suspended in a polymer resin. Fumed silica can also be added to the polymer resin as a thixotropic thickening agent to help stabilize the silver carbon suspension. A conductive element of paper consists of either powdered carbon being impregnated into a paper substrate to form a carbon band or a carbon ribbon being pressed or formed into a paper substrate. The core 15 is typically either aluminum or copper. The process, up to this point, has formed an unprocessed core. Then, in preparation for impregnating, the core 15 is dried to remove all moisture, which includes any hydroscopic moisture associated with the crepe paper, foil matrix 20. The core 15 is then submerged in an epoxy resin bath inside a pressure vessel for impregnating. A vacuum is pulled on the pressure vessel to assists the diffusion of epoxy resin into the core 15. After removal from the epoxy resin bath, the core 15 is then machined on a lathe to its finished dimensions by removing a section of the epoxy resin coating in preparation of the core's surface to receive the silicone-rubber housing 40. During the machining step, either a single or a series of recesses 45 may be cut into the epoxy resin coating. The recesses 45 will later be filled with liquid silicone-rubber, which when the silicone-rubber cures, will provide a physical restraining structure to keep the silicone-rubber housing 40 from slipping on the epoxy resin surface of the core 15. The epoxy resin surface of the core 15 is then sealed with a clear coat track resistant polyurethane. The clear coat track resistant polyurethane is also a primer that increases the silicone-rubber's ability to bond with the core.

The core 15 is then inserted inside a flange 30 designed to securely hold the core 15. The bottom tip of the core 15 extends beyond the bottom edge of the flange 30 by several inches. The core 15 is then placed in a metal mold. The mold is connected to a reservoir of liquid silicone-rubber. A gas, preferably a noble gas, such as nitrogen, can be introduced in the reservoir as back pressure to aid the flow of the liquid silicone-rubber into the mold. The silicone-rubber bonds directly, in a continuous fashion from the top to the bottom of the housing section of the resin impregnated core 15 to form a silicone-rubber housing 40. The silicone-rubber cures and vulcanizes in the mold.

The final step for completing the apparatus bushing is to seal the top of the bushing, just above the silicone-rubber housing 40, with water proof silicone, an O-ring, and a threaded screw on cap 50.

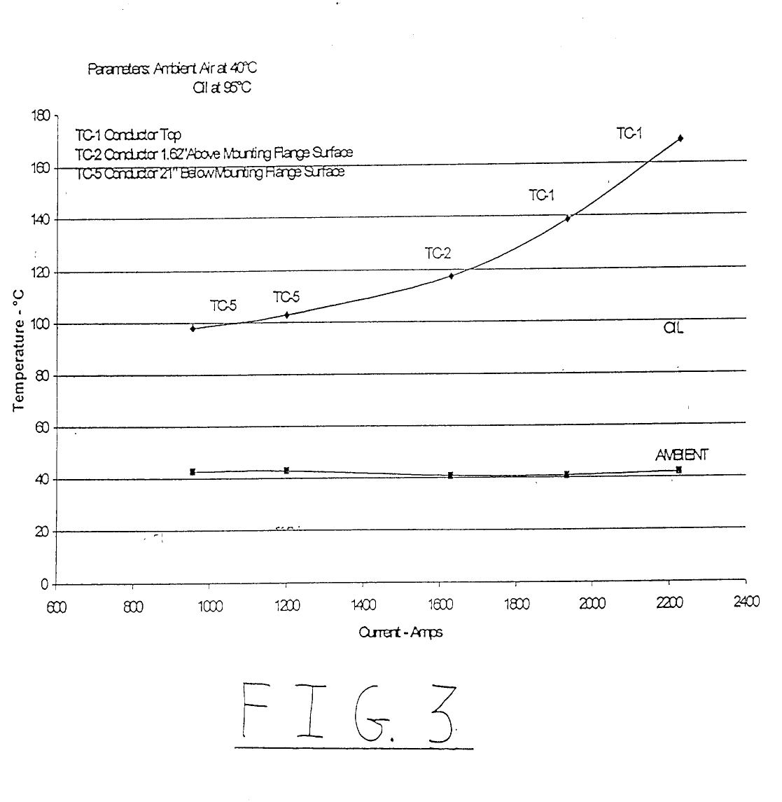

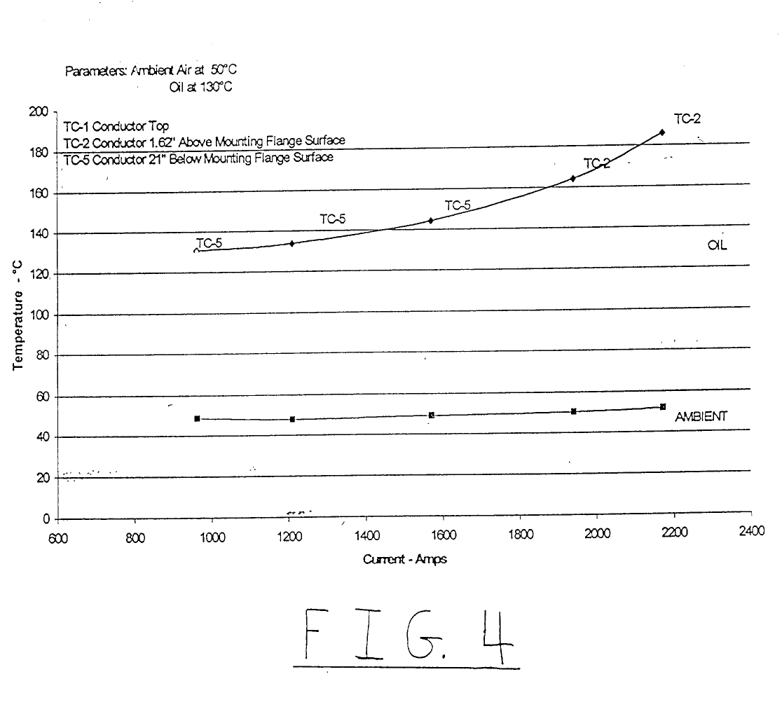

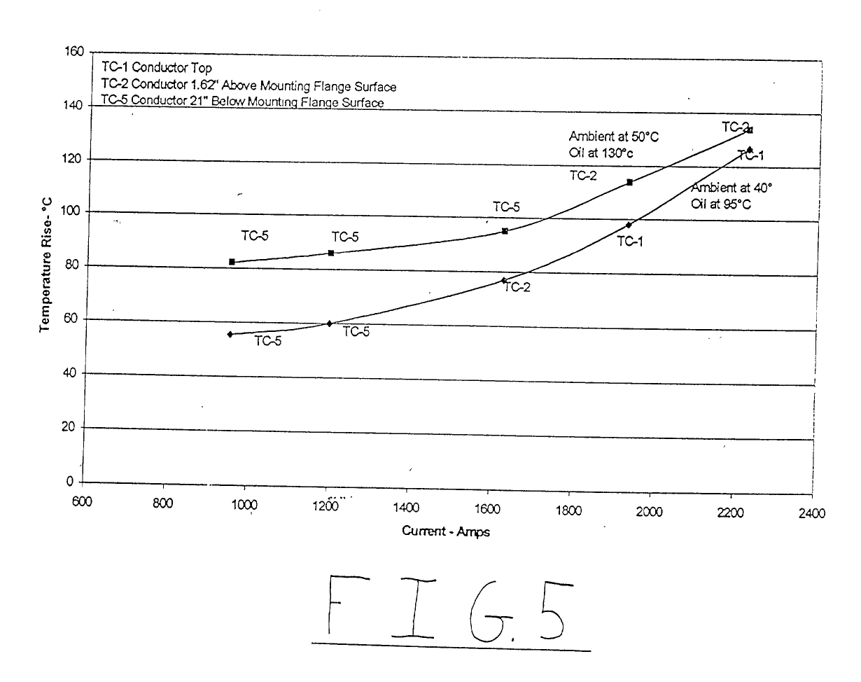

FIGS. 3 through 5 chart the performance of the apparatus bushing as its hot spot is determined at the top of the conductor, 1.62 inches above the mounting flange surface, and 21 inches below the mounting flange surface.

While the invention has been described in terms of preferred embodiments, those skilled in the art will recognize that the invention can be practiced with modification within the spirit and scope of the appended claims.

Having thus described our invention, what we claim as new and desire to secure by Letters Patent is as follows:

1. A method for making a bushing comprising:
Forming a core by securing a plurality of crepe paper, foil matrix layers to a stud;
Drying of said core to remove moisture;
Impregnating said core with an epoxy resin;
Machining of said core to finished dimensions;
Sealing the surface of said core with a polyurethane;
Bonding a flange to said core with an adhesive; and
Molding a housing directly to the surface of said core.

2. A method for making a bushing according to claim 1 wherein: said crepe paper, foil matrix layers is selected from the group consisting of: a metal, a conductive ink, or a conductive element of paper.

3. A method of making a bushing according to claim 1 wherein said Impregnating step is further comprised of:
Submerging said core in an epoxy bath; and
Pressurizing a pressure vessel containing said core and said epoxy bath to force the migration of epoxy into said core.

4. A method of making a bushing according to claim 1 wherein said Machining step is further comprised of:
Cutting at least one recess in said epoxy resin.

5. A method for making a bushing according to claim 1 wherein said Molding step is further comprised of:
Securing said core in a mold;
Introducing a liquid silicone-rubber into said mold; and
Allowing said liquid silicone-rubber sufficient curing time in said mold to vulcanize and retain the interior contour of said mold.

6. A method for making a bushing according to claim 5 wherein said Molding step is further comprised of:
Injecting a gas into a reservoir of liquid silicone-rubber causing a back pressure to assist the flow of said liquid silicone-rubber through a hose connecting said reservoir to said mold.

7. A method for making a bushing according to claim 6 wherein:
said gas is a noble gas.

8. A method for making a bushing according to claim 1 wherein:
said polyurethane is a clear coat track resistant polyurethane.

9. A method for making a bushing according to claim 1 further comprising the step of:
Coating the top of said bushing, just above said housing, with a layer of silicone;
Applying an O-ring on top of said housing; and
Securing a cap to the top of said housing.

10. A method for connecting a housing to an apparatus bushing comprising:
Molding a housing directly to the exterior surface of a core.

11. A method for connecting a housing to an apparatus bushing according to claim 10 wherein:
Said housing consists of silicone-rubber.
